(19) United States
(12) Patent Application Publication
(10) Pub. No.: US 2026/0221975 A1
(43) Pub. Date: Jul. 30, 2026

(54) INTEGRATED CIRCUIT AND PHASE LOCKED LOOP CIRCUIT INCLUDING THE SAME

(71) Applicant: Samsung Electronics Co., Ltd., Suwon-si (KR)

(72) Inventors: Sun Eui PARK, Suwon-si (KR); Dai Hyun LIM, Suwon-si (KR); Kyung Min LEE, Suwon-si (KR)

(21) Appl. No.: 19/447,374

(22) Filed: Jan. 13, 2026

(30) Foreign Application Priority Data
Jan. 24, 2025 (KR) 10-2025-0011318

(51) Int. Cl. H03L 7/099; H03K 5/00; H03K 5/13; H03L 7/093

(52) U.S. Cl. CPC H03L 7/099; H03L 7/093; H03K 2005/00195; H03K 5/13

(57) ABSTRACT

Integrated circuit and PLL circuit are provided. An integrated circuit, which receives a control voltage and converts the control voltage into an oscillator control current, includes a PAR circuit which outputs a compensation current that compensates for at least one of a process variation, a power voltage variation, and a temperature variation of the integrated circuit, an amplifier which includes a first power source terminal that receives a power voltage, a second power source terminal that outputs an amplifier current that determines an amplifier gain, an inverting input terminal that receives the control voltage, and a non-inverting input terminal that receives an amplifier voltage formed on the basis of the amplifier gain, and an IDAC circuit which converts a reference current generated on the basis of the amplifier voltage into the oscillator control current in accordance with an IDAC code. The PAR circuit outputs the compensation current.

### CROSS-REFERENCE TO RELATED APPLICATION

This application claims priority from Korean Patent Application No. 10-2025-0011318 filed on Jan. 24, 2025, in the Korean Intellectual Property Office, and all the benefits accruing therefrom under 35 U.S.C. 119, the contents of which in its entirety are herein incorporated by reference.

### BACKGROUND

The present invention relates to an integrated circuit and a phase locked loop circuit including the same.

An SoC (System on Chip) may use different frequency bands for each embedded constituent element. The SoC includes a plurality of phase locked loop circuits (hereinafter PLL circuits) to support various frequency bands. The PLL circuit performs data transmission with external devices, using an internal clock signal that is locked in synchronization with an external clock signal that is input from the external device in a synchronous semiconductor device. That is, a temporal synchronization between a reference clock signal and data is important for stable data transmission between the synchronous semiconductor device and the external device.

To realize a low-noise and low-power PLL circuit, a ring-shaped voltage control oscillator is used, but the ring oscillator has a disadvantage of being affected by a process variation, a temperature variation, and a power voltage variation.

### SUMMARY

Aspects of the present invention provide an integrated circuit capable of improving bandwidth and stability of a PLL circuit.

Aspects of the present invention also provide a PLL circuit including the integrated circuit capable of improving the bandwidth and stability of the PLL circuit.

However, aspects of the present invention are not restricted to the one set forth herein. The above and other aspects of the present invention will become more apparent to one of ordinary skill in the art to which the present invention pertains by referencing the detailed description of the present invention given below.

According to some embodiments of the present disclosure, there is provided an integrated circuit configured to receive a control voltage and convert the control voltage into an oscillator control current, the integrated circuit comprises a Process Aware Reference (PAR) circuit which is configured to output a compensation current that compensates for at least one of a process variation, a power voltage variation, or a temperature variation of the integrated circuit, an amplifier which includes a first power source terminal that is configured to receive a power voltage, a second power source terminal that is configured to output an amplifier current that determines an amplifier gain, an inverting input terminal that is configured to receive the control voltage, and a non-inverting input terminal that is configured to receive an amplifier voltage based on the amplifier gain, and a current digital-analog converter (IDAC) circuit which is configured to convert a reference current generated based on the amplifier voltage into the oscillator control current in accordance with an IDAC code, wherein the PAR circuit is configured to output the compensation current to adjust the amplifier current.

According to some embodiments of the present disclosure, there is provided an integrated circuit which is configured to receive a control voltage and converts the control voltage into an oscillator control current, the integrated circuit comprises a Process Aware Reference (PAR) circuit which is configured to output a compensation current that compensates for at least one of a process variation, a power voltage variation, or a temperature variation of the integrated circuit, an amplifier which includes an inverting input terminal that is configured to receive the control voltage, and a non-inverting input terminal shorted to a first node, a first transistor which is configured to receive the output voltage of the amplifier as a gate voltage, and has a first end electrically connected to a power source supply terminal, and a second end electrically connected to the first node, a resistor which is electrically connected in series between the first node and a power source ground terminal, a second transistor which is electrically connected in series between a power source terminal of the amplifier and the power source ground terminal, a third transistor which is electrically connected in series between the PAR circuit and the power source ground terminal, and is a current mirror with the second transistor, and a current digital-analog converter (IDAC) circuit which converts a reference current through the resistor into the oscillator control current in accordance with an IDAC code.

According to some embodiments of the present disclosure, there is provided a phase locked loop circuit comprises a loop filter which is configured to output a control voltage based on an amount of charges stored in a capacitor, a voltage-current converter which is configured to receive the control voltage, configured to convert the control voltage into an oscillator control current, and outputs the oscillator control current, and an oscillator which is configured to output an output frequency signal based on the oscillator control current, wherein the voltage-current converter includes a Process Aware Reference (PAR) circuit which is configured to output a compensation current that compensates for at least one of a process variation, a power voltage variation, or a temperature variation of the voltage-current converter, an amplifier which includes a power source terminal that is configured to output an amplifier current that determines an amplifier gain, an inverting input terminal that is configured to receive the control voltage, and a non-inverting input terminal that is configured to receive an amplifier voltage based on the amplifier gain, and a current digital-analog converter (IDAC) circuit which converts a reference current generated based on the amplifier voltage into the oscillator control current in accordance with an IDAC code, wherein the PAR circuit is configured to output the compensation current to adjust the amplifier current.

Specific matters of other embodiments are included in the detailed description and drawings.

### BRIEF DESCRIPTION OF THE DRAWINGS

The above and other aspects and features of the present invention will become more apparent by describing in detail example embodiments thereof. Referring to the attached drawings, in which:

FIG. 1 is a block diagram for explaining a phase locked loop circuit.

FIG. 2 is a circuit diagram for explaining an oscillator.

FIG. 3 is a circuit diagram for explaining a delay cell of FIG. 2.

FIG. 4 is a circuit diagram for explaining a voltage-current converter.

FIG. 5 is a graph showing the change in output frequency signal of the oscillator due to the change in control voltage.

FIG. 6 is a graph showing the change in phase noise due to the change in output frequency signal.

FIG. 7 is a circuit diagram for explaining a voltage-current converter according to some embodiments.

FIG. 8 is a circuit diagram for explaining the structure of a PAR circuit according to some embodiments.

FIG. 9 is a circuit diagram for explaining the structure of a PAR circuit according to some embodiments.

FIG. 10 is a circuit diagram for explaining the structure of a PAR circuit according to some embodiments.

FIG. 11 is a circuit diagram for explaining the three-input amplifier of FIG. 10.

### DETAILED DESCRIPTION OF THE EMBODIMENTS

Hereinafter, embodiments according to the technical idea of the present invention will be described referring to the attached drawings.

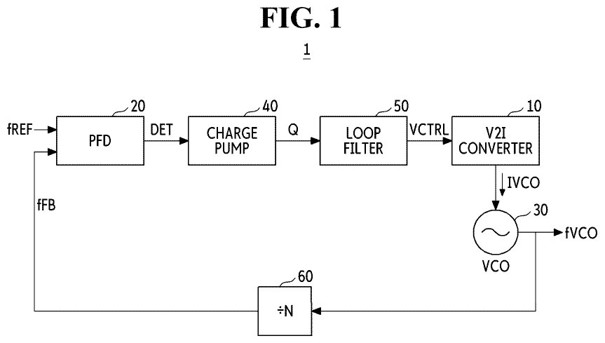

FIG. 1 is a block diagram for explaining a phase locked loop circuit.

Referring to FIG. 1, a phase locked loop (PLL) circuit (hereinafter, “PLL circuit”) 1 may include a voltage-current converter 10, a phase frequency detector 20, an oscillator 30, a charge pump 40, a loop filter 50, and a distributor 60.

The phase frequency detector 20 may receive a reference frequency signal fREF and a feedback frequency signal fFB. The phase frequency detector 20 may compare the phase of the reference frequency signal fREF with the phase of the feedback frequency signal fFB, and output a detection signal DET corresponding to the comparison result. The detection signal DET may be provided to the charge pump 40.

For example, the phase frequency detector 20 may compare the phase of the reference frequency signal fREF with the phase of the feedback frequency signal fFB, and output a detection signal DET having a magnitude of 0 when there is no phase difference. If there is a difference between the phase of the reference frequency signal fREF and the phase of the feedback frequency signal fFB, the phase frequency detector 20 may output a detection signal DET having a pulse width by the section in which the phase difference exists (i.e., corresponding to the phase difference). The sign of the detection signal DET may be determined by comparing the magnitude of the reference frequency signal fREF with the feedback frequency signal fFB.

The charge pump 40 may receive the detection signal DET from the phase frequency detector 20. The charge pump 40 may supply a charge Q to the loop filter 50 in accordance with the detection signal DET. For example, the loop filter 50 may include a capacitor that may store the charge. The charge pump 40 may charge the capacitor of the loop filter 50 when the detection signal DET has a positive sign, and may discharge the capacitor of the loop filter 50 when the detection signal DET has a negative sign. The charge pump 40 may determine the magnitude of the current supplied to the loop filter 50 depending on the pulse width of the detection signal DET.

The loop filter 50 may include a capacitor. The capacitor may store the charge provided from the charge pump 40. The loop filter 50 may provide the control voltage VCTRL to the voltage-current converter 10 on the basis of the amount of charge stored in the capacitor. The loop filter 50 may further include a low pass filter (LPF). The loop filter 50 may remove a noise signal generated in the phase frequency detector 20, using the LPF.

The voltage-current converter 10 may receive the control voltage VCTRL, convert the control voltage VCTRL into an oscillator control current IVCO, and provide it to the oscillator 30.

The oscillator 30 may output an output frequency signal fVCO on the basis of the oscillator control current IVCO. The oscillator 30 may be, for example, a ring oscillator.

The distributor 60 may receive the output frequency signal fVCO from the oscillator 30. The distributor 60 may distribute the frequency of the output frequency signal fVCO on the basis of a defined distribution ratio. For example, the distribution ratio may be adjusted by a signal received from the outside. The distributor 60 may distribute the frequency of the output frequency signal fVCO to output the feedback frequency signal fFB. The feedback frequency signal fFB may be provided to the phase frequency detector 20.

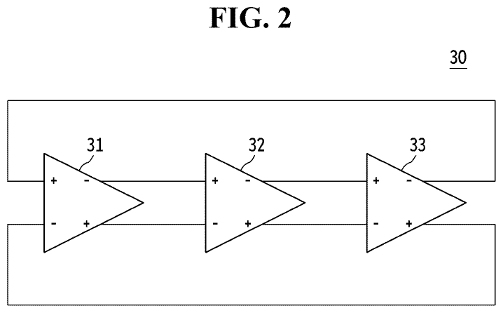

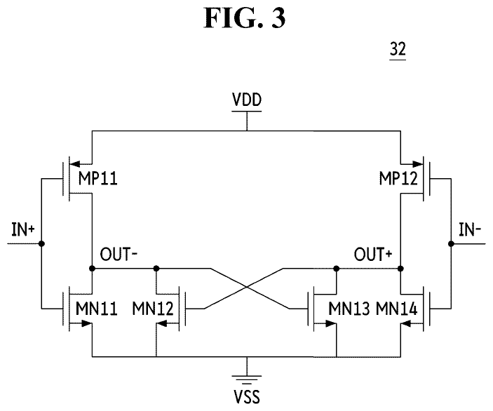

FIG. 2 is a circuit diagram for explaining an oscillator. FIG. 3 is a circuit diagram for explaining a delay cell of FIG. 2.

Referring to FIGS. 2 and 3, the oscillator 30 is a ring oscillator made up of three stages, and may include first, second, and third delay cells 31, 32, and 33. The oscillator 30 may correspond to the oscillator 30 of FIG. 1. In order to more effectively remove common-mode noise, the signal path between the delay cells may be implemented as a differential path.

Each delay cell may include an NMOS transistor and a PMOS transistor. For example, the second delay cell 32 may include PMOS transistor pairs MP11 and MP12 and NMOS transistor pairs MN11 and MN14 that receive an input voltage and output an output voltage, and NMOS transistor pairs MN12 and MN13 that are connected by cross-coupling. The PMOS transistor pairs MP11 and MP12 and the NMOS transistor pairs MN11 and MN14 may receive the differential input voltage (IN+, IN−) at the gates and output the differential output voltage (OUT−, OUT+) at the common drain nodes (MP11-MN11, MP12-MN14) of the PMOS transistors and the NMOS transistors. Each of the NMOS transistor pairs MN12 and MN13 connected by cross coupling has source-drain connected to the same source-drain as the NMOS transistor pairs MN11 and MN14, and a differential output voltage may be provided to the gate.

The differential output signals (OUT+, OUT−) may be generated as a pair of periodic sinusoidal signals, and the output signal OUT+ may have a phase difference of 180 degrees with the output signal OUT−. Next, when the differential output signal is converted into a single-ended signal later, any common-mode noise injected into the input terminal or the power terminal may be canceled.

The second delay cell 32 may adjust the frequency on the basis of a transconductance gm and a load capacitance of the PMOS transistor pairs MP11 and MP12 and the NMOS transistor pairs MN11 and MN14. At this time, the transconductance of the PMOS transistor pairs MP11 and MP12 and the NMOS transistor pairs MN11 and MN14 may be adjusted through a reference current, and may have a wide frequency adjustment band depending on the transconductance to be adjusted. The transconductance GM may be changes in the current divided by the changes in the gate source voltage.

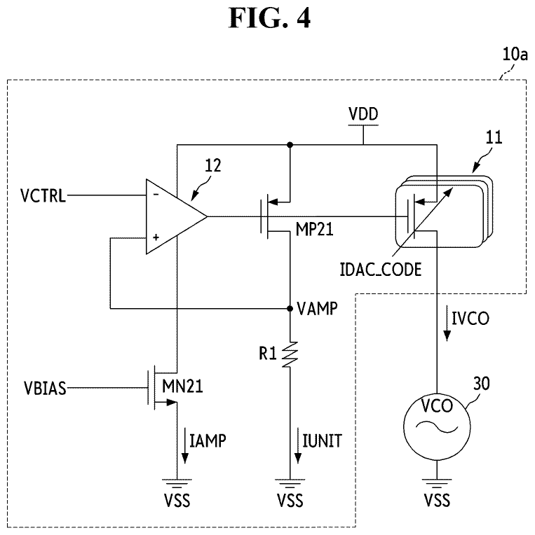

FIG. 4 is a circuit diagram for explaining a voltage-current converter.

Hereinafter, the NMOS transistor and the PMOS transistor described in the circuit diagram and the detailed description of the present invention are examples and not limited thereto. According to some embodiments of the present invention, the NMOS transistor may be realized as a PMOS transistor instead of the NMOS transistor, and the PMOS transistor may be realized as an NMOS transistor instead of the PMOS transistor. The voltage-current converter 10a of FIG. 4 may correspond to the voltage-current converter 10 of FIG. 1. Referring to FIG. 4, the voltage-current converter 10a may include a current digital-analog converter (IDAC) circuit 11 (hereinafter, “IDAC circuit”) and an amplifier 12.

The IDAC circuit 11 may include a plurality of PMOS transistors. The IDAC circuit 11 may convert the reference current IUNIT into the oscillator control current IVCO on the basis of a digital code IDAC_CODE. For example, the IDAC circuit 11 may turn on or off each of the plurality of PMOS transistors depending on the digital code IDAC_CODE. The IDAC circuit 11 may provide the oscillator 30 with the oscillator control current IVCO having the magnitude in which the reference currents IUNIT of the number of turned-on PMOS transistors among the plurality of PMOS transistors are added up. Although the IDAC circuit 11 is realized as a plurality of PMOS transistors in FIG. 4, the IDAC circuit 11 may be realized as a plurality of NMOS transistors according to some embodiments of the present invention.

The amplifier 12 may include an inverting input terminal, a non-inverting input terminal, a first power source terminal, a second power source terminal, and an output terminal. The inverting input terminal may receive a control voltage VCTRL from the outside (for example, the loop filter 50 of FIG. 1). The first power source terminal may be connected to a power source supply terminal VDD. The output terminal of the amplifier 12 is connected to the PMOS transistor MP21, and the output voltage of the amplifier 12 may be supplied to the PMOS transistor MP21 as a gate voltage. The PMOS transistor MP21 may have one end connected to the power source supply terminal VDD, and the other end connected to a first node. An amplifier voltage VAMP may be formed at the first node by the output voltage of the amplifier 12. The non-inverting input terminal of the amplifier 12 may be connected to a first node and provided with the amplifier voltage VAMP. A resistor R1 may be connected in series between the first node and a power source ground terminal VSS. A reference current IUNIT may flow through the resistor R1 due to a voltage difference between the first node and the power source ground terminal VSS. An NMOS transistor MN21 may be connected in series between a second power source terminal of the amplifier 12 and the power source ground terminal VSS. A bias voltage VBIAS may determine the magnitude of an amplifier current IAMP flowing through the NMOS transistor MN21.

The voltage-current converter 10a may be affected by a process variation, a power voltage variation, and/or a temperature variation (PVT change). For example, the bias voltage VBIAS may be affected by the PVT change, and may unintentionally fluctuate in voltage level. In response to a change in bias voltage VBIAS, the amplifier current IAMP may fluctuate in current level as well. A change in magnitude of the amplifier current IAMP may change the gain of the amplifier 12. When the gain of amplifier 12 changes, the output voltage of the amplifier 12 may also change, which may change the magnitude of the amplifier voltage IAMP.

Ideally (when the bias voltage VBIAS is not affected by the PVT change), the magnitude of the amplifier voltage VAMP may be equal to the magnitude of the control voltage VCTRL.

$$IUNIT = \frac{VCTRL}{R 1} , \qquad [ Formula 1 ]$$

$$IVCO = IUNIT \cdot IDAC\_CODE = \frac{VCTRL}{R 1} \cdot IDAC\_CODE$$

However, a voltage difference Voffset may occur between the amplifier voltage VAMP and the control voltage VCTRL due to the PVT change.

$$IUNIT = \frac{VCTRL + Voffset}{R 1} \qquad [ Formula 2 ]$$

Referring to Formula 2, the voltage difference Voffset between the amplifier voltage VAMP and the control voltage VCTRL may reduce the amount of magnitude change in reference current IUNIT due to the magnitude change of the control voltage VCTRL, and may reduce the magnitude change of the output frequency signal fVCO of the oscillator 30 due to the magnitude change of the control voltage VCTRL.

$$L L ( s ) = \frac{ICP \cdot KLF ( s ) \cdot KVCO}{2 π \cdot N \cdot s} , \qquad [ Formula 3 ]$$

$$KVCO = \frac{Δ ( fVCO )}{Δ ( VCTRL )}$$

Referring to Formula 3, a transfer function PLL(s) of the PLL circuit, which determines the bandwidth and stability of the PLL circuit, may be determined by three parameters of a charge pump gain (ICP), a loop filter gain (KLF(s)), and an oscillator gain KVCO. The voltage difference Voffset between the amplifier voltage VAMP and the control voltage VCTRL may change the oscillator gain KVCO, which may inhibit the bandwidth and stability of the PLL circuit.

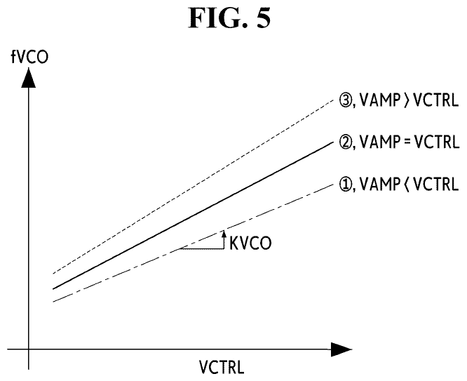

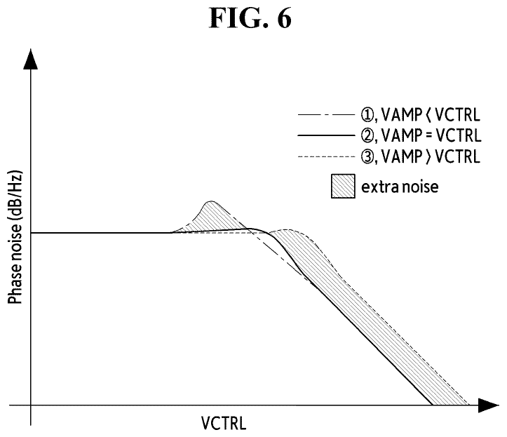

FIG. 5 is a graph showing the change in output frequency signal of the oscillator due to the change in control voltage. FIG. 6 is a graph showing the change in phase noise due to the change in output frequency signal.

A difference in oscillator gain KVCO according to a comparison between the magnitude of the amplifier voltage VAMP and the magnitude of the control voltage VCTRL will be explained referring to FIG. 5. An x-axis of the graph represents the magnitude of the control voltage VCTRL, and a y-axis of the graph represents the frequency of the output frequency signal fVCO. Graph 1 represents the magnitude change of the oscillator output frequency signal due to the magnitude change of the control voltage when the magnitude of the amplifier voltage VAMP is smaller than the magnitude of the control voltage VCTRL. Graph 2 represents the magnitude change of the oscillator output frequency signal due to the magnitude change of the control voltage when the magnitude of the amplifier voltage VAMP is equal to the magnitude of the control voltage VCTRL. Graph 3 represents the magnitude change of the oscillator output frequency signal due to the magnitude change of the control voltage when the magnitude of the amplifier voltage VAMP is larger than the magnitude of the control voltage VCTRL. According to Formula 3, the slope of each graph represents the oscillator gain KVCO. The oscillator gain KVCO is the smallest in Graph 1, and the oscillator gain KVCO is the largest in a.

Next, a difference in phase noise according to a comparison between the magnitude of the amplifier voltage VAMP and the magnitude of the control voltage VCTRL will be explained referring to FIG. 6. An x-axis of the graph represents the frequency of the output frequency signal fVCO, and a y-axis of the graph represents the phase noise. Graph 1 represents a change in phase noise due to a change in output frequency signal when the magnitude of the amplifier voltage VAMP is smaller than the magnitude of the control voltage VCTRL. Graph 2 represents a change in phase noise due to a change in output frequency signal when the magnitude of the amplifier voltage VAMP is equal to the magnitude of the control voltage VCTRL. Graph 3 represents a change in phase noise due to a change in output frequency signal when the magnitude of the amplifier voltage VAMP is greater than the magnitude of the control voltage VCTRL. When there is a voltage difference Voffset due to the difference between the magnitude of the amplifier voltage VAMP and the magnitude of the control voltage VCTRL, an additional noise (hatched portion) may be generated.

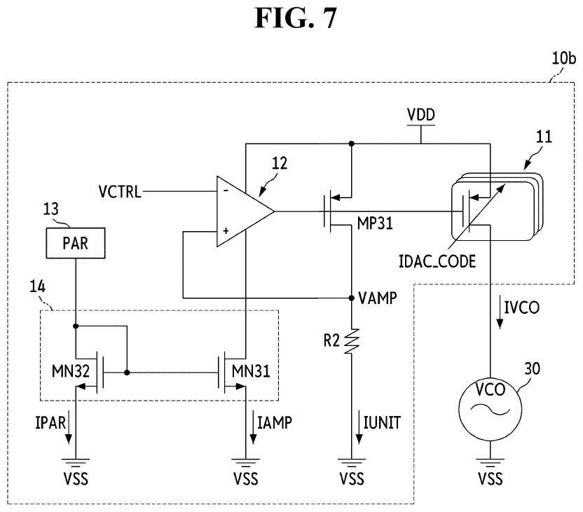

FIG. 7 is a circuit diagram for explaining a voltage-current converter according to some embodiments. Detailed description of the repeated parts of FIG. 4 will not be provided in FIG. 7.

Referring to FIG. 7, the voltage-current converter 10b may further include a PAR (Process Aware Reference) circuit 13, unlike the voltage-current converter 10a of FIG. 4. The PAR circuit 13 may output a compensation current IPAR that compensates for at least one of a process variation, a power voltage variation, and a temperature variation (PVT change). An NMOS transistor MN32 may be connected in series between the PAR circuit 13 and the power source ground terminal VSS. At this time, the NMOS transistor MN31 between the amplifier 12 and the power source ground terminal VSS, and the NMOS transistor MN32 between the PAR circuit 13 and the power source ground terminal VSS may form a current mirror 14. The current mirror 14 may cause the same current as the compensation current IPAR flowing through the NMOS transistor MN32 between the PAR circuit 13 and the power source ground terminal VSS to flow through the NMOS transistor MN31 between the amplifier 12 and the power source ground terminal VSS. That is, the amplifier current IAMP may be substantially equal to the compensation current IPAR. Here, the meaning of “substantially the same” is used to include not only exactly the same thing, but also something similar enough to be treated as the same thing, including an allowable degree of error caused by various factors. The PAR circuit 13 may output the compensation current IPAR to adjust the magnitude of the amplifier current IAMP.

The amplifier current IAMP is equal to the compensation current IPAR in which at least one of the PVT changes is compensated for, and therefore may be resistant to the PVT changes. The voltage difference Voffset between the amplifier voltage VAMP and the control voltage VCTRL may decrease by the amplifier current IAMP which is resistant to PVT changes.

According to some embodiments, since the voltage-current converter 10b further includes a PAR circuit 13, it is possible to reduce the voltage difference Voffset between the magnitude of the amplifier voltage VAMP and the control voltage VCTRL. Thus, it is possible to provide a voltage-current converter 10b that may improve the bandwidth and stability of the PLL circuit.

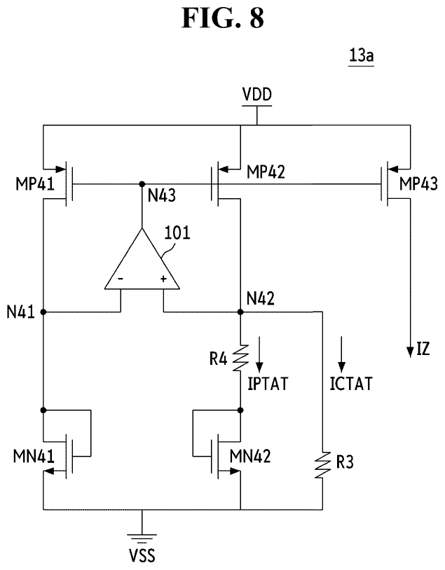

FIG. 8 is a circuit diagram for explaining the structure of a PAR circuit according to some embodiments.

The structure of the PAR circuit will be described below, but the PAR circuit is not limited only to the structure described in this disclosure, and the PAR circuit may have various structures other than the structure described in this disclosure.

Referring to FIG. 8, a PAR circuit 13a may include an amplifier 101, NMOS transistor pairs MN41 and MN42, PMOS transistors MP41, MP42 and MP43, and resistors R3 and R4. The NMOS transistor pairs MN41 and MN42 may be connected between the power source ground terminal VSS and the N41 node, and between the power source ground terminal VSS and the N42 node, respectively. The NMOS transistor pairs MN41 and MN42 may have a source terminal connected to the power source ground terminal VSS, and a drain terminal may be connected to the gate terminal, thereby forming a diode connection. The gate-source voltage may be applied to the gate of the NMOS transistor MN41, and the gate-source voltage may be applied to the gate of the NMOS transistor MN42.

The NMOS transistor MN42 may be connected between the power source ground terminal VSS and the first terminal (+) of the amplifier 101, and the NMOS transistor MN41 may be connected between the power source ground terminal VSS and the second terminal (−) of the amplifier 101. A resistor R4 is connected between NMOS transistor MN42 and N42 node, and a resistor R3 may be connected in parallel with the NMOS transistor MN42, i.e., between the power source ground terminal VSS and the N42 node.

The PMOS transistor pairs MP41 and MP42 may be connected between the N41 node and the power source supply terminal VDD, and between the N42 node and the power source supply terminal VDD, respectively. Gate terminals of the PMOS transistors MP41, MP42 and MP43 may be connected to the output node N43 of the amplifier.

Current I_{DS} flowing through the NMOS transistor MN41 may be calculated as shown in Formula 4, when the NMOS transistor MN41 of the PAR circuit 13a operates in a sub-threshold region.

$${I}_{DS} = μ {C}_{ox} \frac{W}{L} ( η - 1 ) {V}_{T}^{2} {exp}^{( \frac{{V}_{GS 1} - {V}_{th}}{η {V}_{T}} )} \qquad [ Formula 4 ]$$

In the above Formula, V_{GS1} means a gate-source voltage of the NMOS transistor MN41, Vₜₕ means a threshold voltage of the NMOS transistor MN41, η means a sub-threshold slope factor of the transistor MN41, T means an absolute temperature, and V_{T} means a thermal voltage proportional to the absolute temperature.

The diode-connected NMOS transistor MN41 may have a voltage V_{GS1} that has a negative coefficient in a temperature-voltage relationship, and the current that is proportional to the voltage may be a complementary to absolute temperature (CTAT) that has a negative coefficient relative to the absolute temperature. Further, because the threshold voltage Vₜₕ of the NMOS transistor MN41 may change due to the process variation, information on the process variation of the NMOS transistor may be obtained through the voltage V_{GS1}. The CTAT current ICTAT=V_{GS1}/R3 may flow through the resistor R3 according to the voltage V_{GS1} due to the parallel connection.

Further, the NMOS transistor MN41 may have a different size from the NMOS transistor MN42. The NMOS transistor MN41 may have a size difference of n times from the NMOS transistor MN42. Since the temperature characteristics may vary when the sizes of the NMOS transistor MN41 and NMOS transistor MN42 are different, PTAT (Proportional To Absolute Temperature) characteristics may be created on the basis of the voltage difference between the two transistors. The PTAT current based on the size difference between both the transistors MN41 and MN42 is proportional to the absolute temperature T as in Formula 5.

$$Δ {V}_{GS} = {V}_{GS 1} - {V}_{GS 2} = {V}_{T} ln \frac{{nI}_{DS 1}}{{I}_{01}} - {V}_{T} ln \frac{{I}_{DS 2}}{{I}_{02}} = {V}_{T} ln n = \frac{kT}{q} ln n \qquad [ Formula 5 ]$$

In Formula 5, V_{GS2} is a gate-source voltage of the NMOS transistor MN42, V_{GS1} is a gate-source voltage of the NMOS transistor MN41, I_{DS1} is a drain-source current of the NMOS transistor MP41, and I_{DS2} is a drain-source current of the PMOS transistor MN42. Here, n is a size ratio of the NMOS transistor MN42 to the NMOS transistor MN41, and T is an absolute temperature.

ΔV_{GS} of the PTAT current PTAT may be proportional to the absolute temperature T. The transistors MN41 and MN42 may generate a PTAT current (IPTAT=ΔV_{GS}/R4) based on the resistor R4 and ΔV_{GS}, and the PTAT current PTAT may be proportional to the absolute temperature T.

The compensation current Iz of the PAR circuit 13a may be generated by adding up the PTAT current and the CTAT current as in Formula 6.

$$Iz = \frac{{V}_{GS 1}}{R 3} + \frac{Δ {V}_{GS 2}}{R 4} = \frac{1}{R 3} ( {V}_{GS 1} + \frac{R 3}{R 4} Δ {V}_{GS} ) \qquad [ Formula 6 ]$$

According to Formula 6, the PAR circuit 13a may make a constant current flow regardless of temperature changes by adjusting the ratio of the resistors R3 and R4.

Further, V_{GS1} of the NMOS transistor MN41 varies according to the process variation of the NMOS transistor process, and therefore it may possible to obtain information about the process variation through the changing current, and compensate for the process variation. However, in a general VCO, because both the NMOS and PMOS transistors are affected by the process variation, in order to compensate for the VCO, it may be necessary to configure like not only the PAR circuit 13a designed as the NMOS transistor, but also other circuits designed as the PMOS transistor.

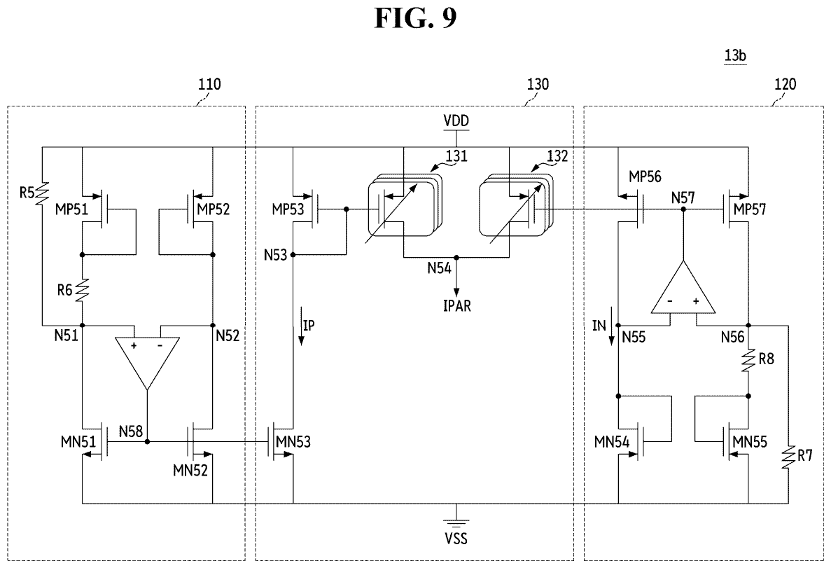

FIG. 9 is a circuit diagram for explaining the structure of a PAR circuit according to some embodiments.

Referring to FIG. 9, the PAR circuit 13b may include bandgap reference circuit pairs 110 and 120 and a weighted current mirror 130.

The bandgap reference circuit pairs 110 and 120 may include a first type bandgap reference circuit 110 and a second type bandgap reference circuit 120 which are each connected to both ends of the weighted current mirror 130.

According to some embodiments, the first type bandgap reference circuit 110 and the second type bandgap reference circuit 120 may have a twin structure. That is, the first type bandgap reference circuit 110 and the second type bandgap reference circuit 120 may be realized in the same circuit connection structure, with the only difference being whether they are realized as a PMOS transistor circuit or an NMOS transistor circuit.

For example, the first type bandgap reference circuit 110 may include an amplifier, PMOS transistor pairs MP51 and MP52, NMOS transistor pairs MN51 and MN52, and resistors R5 and R6.

The PMOS transistor pairs MP51 and MP52 may be connected between the power source supply terminal VDD and the N51 node, and between the power source supply terminal VDD and the N52 node, respectively. The PMOS transistors MP51 and MP52 may have source terminals connected to the power source supply terminal VDD, and drain terminals connected to the gate terminals, thereby forming diode connections. The gate-source voltage may be applied to the gate of the PMOS transistor MP51, and the gate-source voltage may be applied to the gate of the PMOS transistor MP52.

The PMOS transistor MP51 may be connected between the power source supply terminal VDD and the first terminal (+) of the amplifier, and the PMOS transistor MP52 may be connected between the power source supply terminal VDD and the second terminal (−) of the amplifier. The resistor R6 may be connected between the PMOS transistor MP51 and the N51 node, and the resistor R5 may be connected in parallel with the PMOS transistor MP51, that is, between the power source supply terminal VDD and the N51 node.

The NMOS transistor pairs MN51 and MN52 may be connected between the N51 node and the power source ground terminal VSS, and between the N52 node and the power source ground terminal VSS, respectively. The gate terminals of the NMOS transistor pairs MN51 and MN52 may be connected to the output node N58 of the amplifier.

When the PMOS transistor MP52 of the first type bandgap reference circuit 110 operates in the sub-threshold region, the current IDS flowing through the PMOS transistor MP52 is as in Formula (7).

$${I}_{DS} = μ {C}_{ox} \frac{W}{L} ( η - 1 ) {V}_{T}^{2} {exp}^{( \frac{{V}_{GSP 1} - {V}_{th}}{η {V}_{T}} )} \qquad [ Formula 7 ]$$

In the above Formula, V_{GSP1} means a gate-source voltage of the transistor MP52, Vth means a threshold voltage of the transistor MP52, η means a sub-threshold slope factor of the transistor MP52, T means an absolute temperature, and VT means a thermal voltage proportional to the absolute temperature T.

The diode-connected PMOS transistor MP52 may have a voltage V_{GSP1} with a negative coefficient in the temperature-voltage relationship, and the current proportional to the voltage may be a complementary to absolute temperature (CTAT) current with a negative coefficient relative to the temperature. That is, the CTAT current flowing through the resistor R5 may be ICTAT=V_{GSP1}/R5.

The PMOS transistor MP51 may have a different size from the PMOS transistor MP52. The PMOS transistor MP51 may have a size difference of n times from the PMOS transistor MP52. Since the temperature characteristics vary when the sizes of the PMOS transistors MP51 and MP52 are different, the PTAT (Proportional To Absolute Temperature) characteristics may be created on the basis of the voltage difference between the two transistors. The PTAT current based on the size difference between the two transistors MP51 and MP52 is proportional to the absolute temperature T as in Formula 8.

$$Δ {V}_{GSP} = {V}_{GSP 2} - {V}_{GSP 1} = {V}_{T} ln \frac{{nI}_{DS 2}}{{I}_{02}} - {V}_{T} ln \frac{{I}_{DS 1}}{{I}_{01}} = {V}_{T} ln n = \frac{kT}{q} ln n \qquad [ Formula 8 ]$$

In Formula 8, V_{GSP2} is a gate-source voltage of the PMOS transistor MP51, V_{GSP1} is a gate-source voltage of the PMOS transistor MP52, I_{DS2} is a drain-source current of the PMOS transistor MP51, and I_{DS1} is a drain-source current of the PMOS transistor MP2. n is a size ratio of the PMOS transistor MP51 relative to the PMOS transistor MP52, and T is an absolute temperature.

In the shown example, the PMOS transistor MP51 will be described as having a size eight times that of the PMOS transistor MP52. That is, as a non-limiting example, V_{GSP2} has a gate-source voltage eight times larger than V_{GSP1}. However, embodiments of the present invention is not limited thereto, and the size difference between the two transistors may be set in various ways according to various embodiments.

That is, according to Formula 8, since a body-effect influence between the two transistors MP51 and MP52 is slight, ΔV_{GSP} is proportional to the absolute temperature T, assuming that the threshold voltages Vth are approximately the same. The transistors MP51 and MP52 generate a PTAT current (IPTAT=ΔV_{GSP}/R6) based on the resistor R6 and ΔV_{GSP}, and the PTAT current PTAT is proportional to the absolute temperature T.

The first type bandgap reference circuit 110 may generate the first type compensation current IP on the basis of such characteristics. The first type compensation current IP is calculated as in Formula 9.

$$IP = \frac{{V}_{GSP 1}}{R 5} + \frac{Δ {V}_{GSP}}{R 6} = \frac{1}{R 5} ( {V}_{GSP 1} + \frac{R 5}{R 6} Δ {V}_{GSP} ) \qquad [ Formula 9 ]$$

That is, the first type compensation current IP is a value obtained by adding the CTAT current ICTAT inversely proportional to the absolute temperature and the PTAT current IPTAT proportional to the absolute temperature, and a constant current independent of temperature may be output by adjusting the ratio of the two resistors R5 and R6.

The second type bandgap reference circuit 120 may include an amplifier, NMOS transistor pairs MN54 and MN55, PMOS transistor pairs MP56 and MP57, and resistors R7 and R8.

The NMOS transistor pairs MN54 and MN55 may be connected between the power source ground terminal VSS and the N55 node, and between the power source ground terminal VSS and the N56 node, respectively. The NMOS transistor pairs MN54 and MN55 may have source terminals connected to the power source ground terminal VSS, and drain terminals connected to the gate terminal, thereby forming a diode connection. A gate-source voltage may be applied to a gate of the NMOS transistor MN54 has, and a gate-source voltage may be applied to a gate of the NMOS transistor MN55.

The NMOS transistor MN55 may be connected between the power source ground terminal VSS and the first terminal (+) of the amplifier, and the NMOS transistor MN54 may be connected between the power source ground terminal VSS and the second terminal (−) of the amplifier. A resistor R8 may be connected between the NMOS transistor MN55 and the node N56, and a resistor R7 may be connected in parallel with the NMOS transistor MN55, that is, between the power source ground terminal VSS and the node N56.

The PMOS transistor pairs MP56 and MP57 may be connected between the node N55 and the power source supply terminal VDD, and between the node N56 and the power source supply terminal VDD, respectively. The gate terminals of the PMOS transistor pairs MP56 and MP57 may be connected to the output node N58 of the amplifier.

The second type compensation current IN of the second type bandgap reference circuit 120 is as in the following Formula 10, as described in FIG. 8.

$$IN = \frac{{V}_{GSN 1}}{R 7} + \frac{Δ {V}_{GSN}}{R 8} = \frac{1}{R 7} ( {V}_{GSN 1} + \frac{R 7}{R 8} Δ {V}_{GSN} ) \qquad [ Formula 10 ]$$

The weighted current mirror 130 may include a diode-connected PMOS transistor MP53 and an NMOS transistor MN53 for converting the first type compensation current IP generated by the first type bandgap reference circuit 110 at the N52 node.

The first bandgap reference circuit 110 generates a first type compensation current IPAR flowing from the NMOS transistor MN52 to the PMOS transistor MP52, but the weighted current mirror 130 may invert a current direction, by including auxiliary current mirror circuits MP53 and MN53 for weighted averaging with the second type compensation current IPAR.

The weighted current mirror 130 may generate a summed compensation current obtained by weighted averaging of the first type compensation current IP and the second type compensation current IN. The weighted current mirror 130 may generate and output a summed compensation current IPAR as in Formula 11.

$$IPAR = a \cdot IP + ( 1 - a ) \cdot IN \qquad [ Formula 11 ]$$

The PLL circuit (e.g., the PLL circuit 1 of FIG. 1) includes at least one PMOS transistor and at least one NMOS transistor, and may be affected by both the PMOS transistor process and the NMOS transistor process. Even if the PLL circuit is affected by the above two processes, the PAR circuit 13b may adjust the influence of the PMOS transistor process with a weighted value a of the first type compensation current IP generated by the first type bandgap reference circuit 110, and may adjust the influence of the NMOS transistor process with a weighted value (1−a) of the second type compensation current generated by the second type bandgap reference circuit 120, thereby adjusting a frequency deviation according to the process.

According to some embodiments, the weighted current mirror 130 may further include a plurality of first type weighting circuits 131 and second type weighting circuits 132 that are output by weighted average of the first type compensation current IP and the second type compensation current IN. The first and second type weighting circuits 131 and 132 may include a plurality of PMOS transistors. The first type weighting circuit 131 may be connected between a power source supply terminal VDD and a summing output node N54, and the gates may be connected to the first type bandgap reference circuit 110. The second type weighting circuit 132 may be connected between the power source supply terminal VDD and the summing output node N54, and the gates may be connected to the second type bandgap reference circuit 120. The first type weighting circuit 131 and the second type weighting circuit 132 may output a summed compensation current IPAR that is weighted and averaged through the summing output node N54.

In order to reflect the weighted values, each of the first type weighting circuit 131 and the second type weighting circuit 132 may include PMOS transistors having the same size. The weighted current mirror 130 may adjust the weighted value a: (1-a) by changing the number of transistors that are turned on or off, among the first type weighting circuit 131 and the second type weighting circuit 132.

Also, unlike that shown in FIG. 9, each of the first type weighting circuit and the second type weighting circuit may include a plurality of NMOS transistors. The first type weighting circuit and the second type weighting circuit may be connected between the power source ground terminal VSS and the summing output node N54, and the gates may be connected to each of the first bandgap reference circuit 110 and the second bandgap reference circuit 120.

The PAR circuit 13b may generate a summed compensation current IPAR that is less affected by PVT changes, by adjusting the weighted value in consideration of the magnitude changes of the first type compensation current IPAR and the second type compensation current IPAR according to the PVT changes.

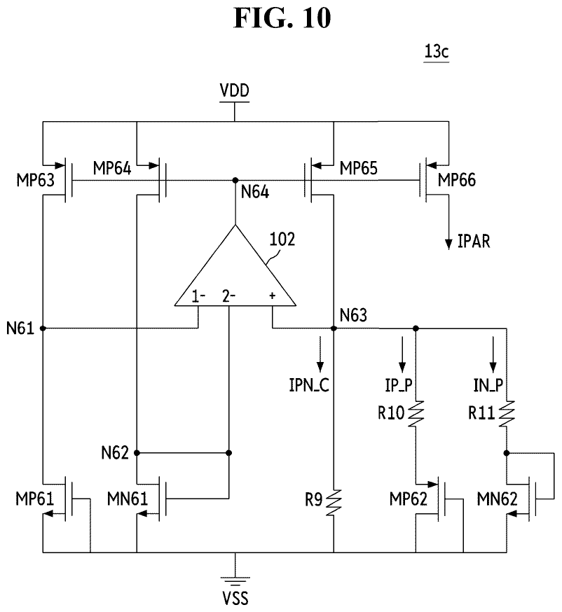

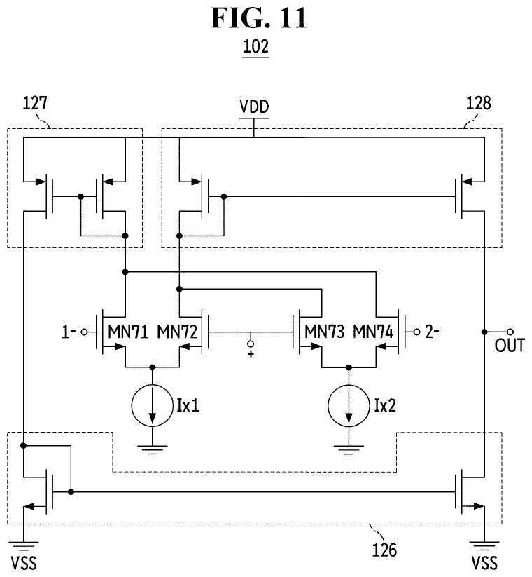

FIG. 10 is a circuit diagram for explaining the structure of a PAR circuit according to some embodiments. FIG. 11 is a circuit diagram for explaining the three-input amplifier of FIG. 10.

Referring to FIGS. 10 and 11, a PAR circuit 13c may be the PAR circuit 13 of FIG. 4. The PAR circuit 13c may include a three-input amplifier 102, NMOS transistor pairs MN61 and MN62, PMOS transistor pairs MP61 and MP62, PMOS transistors MP63, MP64, MP65 and MP66, and resistors R9, R10 and R11. The NMOS transistor pairs MN61 and MN62 may be connected between the power source ground terminal VSS and the N42 node, and between the power source ground terminal VSS and the N43 node, respectively. The NMOS transistor pairs MN61 and MN62 may have a source terminal connected to the power source ground terminal VSS, and a drain terminal connected to the gate terminal, thereby forming a diode connection. The gate-source voltage of the NMOS transistor MN61 may be applied to the gate, and the gate-source voltage of the NMOS transistor MN62 may be applied to the gate. The PMOS transistor pairs MP61 and MP62 may be connected between the power source ground terminal VSS and the N61 node, and between the power source ground terminal VSS and the N63 node, respectively. The PMOS transistor pairs MP61 and MP62 have a drain terminal connected to the power source ground terminal VSS, and the drain terminal may be connected to the gate terminal to form a diode connection.

The NMOS transistor MN62 may be connected between the power source ground terminal VSS and the first terminal (+) of the three-input amplifier 102, and the NMOS transistor MN61 may be connected between the power source ground terminal VSS and the third terminal (2−) of the three-input amplifier 102. The PMOS transistor MP62 may be connected between the power source ground terminal VSS and the first terminal (+) of the three-input amplifier 102, and the PMOS transistor MN61 may be connected between the power source ground terminal VSS and the first terminal (+) of the three-input amplifier 102, and the PMOS transistor MN61 may be connected between the power source ground terminal VSS and the second terminal (1−) of the three-input amplifier 102. The resistor R10 may be connected between the PMOS transistor MN62 and the N63 node, the resistor R11 may be connected between the NMOS transistor MN62 and the N63 node, and the resistor R9 may be connected between the power source ground terminal VSS and the N63 node.

The three-input amplifier 102 has a first terminal (+), a second terminal (1−), and a third terminal (1+) as input terminals, and may include current mirrors 126, 127, and 128. The first terminal (+) may be connected to the gate terminals of the NMOS transistors MN72 and MN73, and each of the second terminal (1−) and the third terminal (2−) may be connected to the gate terminals of the NMOS transistors MN71 and MN74. At this time, a first summed current flowing through the NMOS transistors MN71 and MN72 may be Ix1=a·Ix. A second summed current flowing through the NMOS transistors MN73 and MN74 may be Ix2=(1−a)·Ix. Therefore, the voltage applied to the first terminal (+) of the three-input amplifier 102 may be V_{GSA}=aV_{GSP1}+(1−a)V_{GSN1}.

The PMOS transistors MP63, MP64, and MP65 may be connected between the N61 node and the power source supply terminal VDD, between the N62 node and the power source supply terminal VDD, and between the N63 node and the power source supply terminal VDD, respectively. The gate terminals of the PMOS transistors MP63, MP64, MP65, and MP66 may be connected to the output node N64 of the three-input amplifier 102.

Referring to the aforementioned contents, since the source voltage V_{GSP1} of the PMOS transistor MP61 and the gate-drain voltage V_{GSN1} of the NMOS transistor MN61 have negative coefficients in the temperature-voltage relationship, the current IPN_C flowing through the resistor R9 is as in the following Formula 12, and may be a CTAT (Complementary to Absolute Temperature) current based on the NMOS and PMOS transistors having a negative coefficient relative to the temperature.

$$IPN\_C = ( a \cdot {V}_{GSP 1} + ( 1 - a ) \cdot {V}_{GSN 1} ) / R 9 \qquad [ Formula 12 ]$$

Similarly, referring to the aforementioned contents, PTAT (Proportional To Absolute Temperature) characteristics proportional to the absolute temperature T may be created, by the difference in temperature characteristics due to the size difference between the PMOS transistor MP61, the NMOS transistor MN61, and the PMOS transistor MP62. Also, PTAT (Proportional To Absolute Temperature) characteristics proportional to the absolute temperature T may be created, by the difference in temperature characteristics due to the size difference between the PMOS transistor MP61, the NMOS transistor MN61 and the NMOS transistor MN62. Therefore, the current IP_P flowing through the resistor R10 is as in the following Formula 13, and may be a PTAT current based on the PMOS transistor proportional to the absolute temperature T. Also, the current IN_P flowing through the resistor R11 is as in the following Formula 14, and may be a PTAT current based on the NMOS transistor proportional to the absolute temperature T.

$$IP\_P = ( a \cdot {V}_{GSP 1} + ( 1 - a ) \cdot {V}_{GSN 1} - {V}_{GSP 2} ) / R 10 \qquad [ Formula 13 ]$$

$$IN\_P = ( a \cdot {V}_{GSP 1} + ( 1 - a ) \cdot {V}_{GSN 1} - {V}_{GSN 2} ) / R 11 \qquad [ Formula 14 ]$$

Finally, the IPAR current flowing through the PMOS transistor MP66 may be equal to the sum of the CTAT current of the NMOS and PMOS, the PTAT current of the PMOS, and the PTAT current of the NMOS, as in the following Formula 15.

$$IPAR = IPN\_C + IP\_P + IN\_P \qquad [ Formula 15 ]$$

The PLL circuit (e.g., the PLL circuit 1 of FIG. 1) may be affected by both the PMOS transistor process and the NMOS transistor process, by including at least one PMOS transistor and at least one NMOS transistor. According to some embodiments, even if the PLL circuit is affected by both the PMOS transistor process and the NMOS transistor process, the PAR circuit 13c may adjust the influence of the PMOS and NMOS transistor processes to the weighted value a, thereby compensating for both the process variation of the NMOS process and the process variation of the PMOS process. At this time, the PLL circuit may adjust the transconductance value of the three-input amplifier 102 to adjust the weighted value a. For example, the weighted value a may be adjusted, by adjusting the transconductance values of the NMOS transistors MN71, MN72, MN73, and MN74 of FIG. 11. In addition, the PLL circuit may output a current irrelevant to the temperature changes by adjusting the ratio of the resistors R9, R10, and R11.

According to some embodiments, the compensation current IPAR generated by the PAR circuit 13c may vary with the change in PVT. That is, the compensation current IPAR may reflect the PMOS transistor process, change due to the process variation or temperature of the NMOS transistor, changes in the power voltage, or changes due to the power voltage noise. The compensation current IPAR may be changed in response to PVT changes of the same environmental conditions as the transistors included in other components included in the PLL circuit.

According to some embodiments, the PAR circuit 13c may generate a compensation current IPAR that is less affected by a process variation, a temperature variation, and a power voltage variation, by adjusting the weighted value a and the resistance ratio in consideration of the PVT changes.

Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

Although some embodiments of the present disclosure have been described above with reference to the accompanying diagrams, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

1. An integrated circuit configured to receive a control voltage and convert the control voltage into an oscillator control current, the integrated circuit comprising:
a Process Aware Reference (PAR) circuit configured to output a compensation current that compensates for at least one of a process variation, a power voltage variation, or a temperature variation of the integrated circuit;
an amplifier comprising:
a first power source terminal configured to receive a power voltage,
a second power source terminal configured to output an amplifier current that determines an amplifier gain,
an inverting input terminal configured to receive the control voltage, and
a non-inverting input terminal configured to receive an amplifier voltage based on the amplifier gain; and
a current digital-analog converter (IDAC) circuit configured to convert a reference current generated based on the amplifier voltage into the oscillator control current in accordance with an IDAC code,
wherein the PAR circuit is configured to output the compensation current to adjust the amplifier current.

2. The integrated circuit of claim 1,
wherein a magnitude of the amplifier current is substantially equal to a magnitude of the compensation current.

3. The integrated circuit of claim 1, further comprising:
a resistor which is electrically connected in series between a first node that provides an amplifier voltage to the non-inverting input terminal and a ground power source terminal,
wherein the reference current is a current through the resistor.

4. The integrated circuit of claim 1,
wherein the PAR circuit includes a first type bandgap reference circuit configured to generate a first type compensation current, and a second type bandgap reference circuit configured to generate a second type compensation current, and
wherein the compensation current is based on a weighted average of the first type compensation current and the second type compensation current.

5. The integrated circuit of claim 4, wherein the first type bandgap reference circuit comprises:
a first amplifier;
first diode-connected PMOS transistor pairs that are electrically connected between a power source supply terminal and input terminals of the first amplifier; and
first NMOS transistor pairs which have gates electrically connected to an output terminal of the first amplifier, and are electrically connected between the input terminals of the first amplifier and a power source ground terminal.

6. The integrated circuit of claim 5, wherein the first type bandgap reference circuit comprises:
a first resistor electrically connected between the power source supply terminal and a first input terminal of the input terminals of the first amplifier,
a first diode-connected PMOS transistor and a second resistor which are electrically connected in series between the power source supply terminal and the first input terminal of the first amplifier,
a second diode-connected PMOS transistor which is electrically connected between the power source supply terminal and a second input terminal of the input terminals of the first amplifier,
a first NMOS transistor which is electrically connected between the first input terminal of the first amplifier and the power source ground terminal, and has a gate terminal electrically connected to the output terminal of the first amplifier, and
a second NMOS transistor which is electrically connected between the second input terminal of the first amplifier and the power source ground terminal, and has a gate terminal electrically connected to the output terminal of the first amplifier.

7. The integrated circuit of claim 4, wherein the PAR circuit includes a weighted current mirror which is configured to receive the first type compensation current and weights it with a first gain to produce a weighted first type compensation current, configured to receive the second type compensation current and weights it with a second gain to produce a weighted second type compensation current, and configured to output the compensation current by summing up the weighted first type compensation current and the weighted second type compensation current.

8. The integrated circuit of claim 1, wherein the PAR circuit comprises:
a three-input amplifier which includes a first input terminal, a second input terminal, and a third input terminal,
a first diode-connected PMOS transistor which is electrically connected between the first input terminal of the three-input amplifier and a power source ground terminal,
a first diode-connected NMOS transistor which is electrically connected between the second input terminal of the three-input amplifier and the power source ground terminal, and
a first resistor which is electrically connected between the third input terminal of the three-input amplifier and the power source ground terminal.

9. The integrated circuit of claim 8,
wherein the three-input amplifier includes first, second, third, and fourth amplifier transistors,
wherein the first input terminal of the three-input amplifier is electrically connected to a gate terminal of the first amplifier transistor,
wherein the second input terminal of the three-input amplifier is electrically connected to a gate terminal of the fourth amplifier transistor, and
wherein the third input terminal of the three-input amplifier is electrically connected to gate terminals of the second amplifier transistor and the third amplifier transistor.

10. The integrated circuit of claim 8, wherein the PAR circuit further comprises:
a second diode-connected PMOS transistor which is electrically connected between the third input terminal of the three-input amplifier and the power source ground terminal, and has a size larger than that of the first PMOS transistor; and
a second resistor electrically connected between the third input terminal of the three-input amplifier and the second PMOS transistor.

11. The integrated circuit of claim 8, wherein the PAR circuit further comprises:
a second diode-connected NMOS transistor which is electrically connected between the third input terminal of the three-input amplifier and the power source ground terminal, and has a size larger than that of the first NMOS transistor; and
a second resistor electrically connected between the third input terminal of the three-input amplifier and the second NMOS transistor.

12. An integrated circuit configured to receive a control voltage and convert the control voltage into an oscillator control current, the integrated circuit comprising:
a Process Aware Reference (PAR) circuit configured to output a compensation current that compensates for at least one of a process variation, a power voltage variation, or a temperature variation of the integrated circuit;
an amplifier comprising an inverting input terminal that is configured to receive the control voltage, and a non-inverting input terminal shorted to a first node;
a first transistor configured to receive an output voltage of the amplifier as a gate voltage, and has a first end electrically connected to a power source supply terminal, and a second end electrically connected to the first node;
a resistor which is electrically connected in series between the first node and a power source ground terminal;
a second transistor which is electrically connected in series between a power source terminal of the amplifier and the power source ground terminal;
a third transistor which is electrically connected in series between the PAR circuit and the power source ground terminal, and is a current mirror with the second transistor; and
a current digital-analog converter (IDAC) circuit which is configured to convert a reference current through the resistor into the oscillator control current in accordance with an IDAC code.

13. The integrated circuit of claim 12,
wherein the PAR circuit includes a first type bandgap reference circuit configured to generate a first type compensation current, and a second type bandgap reference circuit configured to generate a second type compensation current, and
wherein the compensation current is a weighted average of the first type compensation current and the second type compensation current.

14. The integrated circuit of claim 13, wherein the first type bandgap reference circuit comprises:
a first amplifier;
first diode-connected PMOS transistor pairs that are electrically connected between a power source supply terminal and input terminals of the first amplifier; and
first NMOS transistor pairs which have gates electrically connected to an output terminal of the first amplifier, and are electrically connected between the input terminal of the first amplifier and the power source ground terminal.

15. The integrated circuit of claim 14, wherein the first type bandgap reference circuit comprises:
a first resistor which is electrically connected between the power source supply terminal and a first input terminal of the first amplifier,
a first diode-connected PMOS transistor and a second resistor which are electrically connected in series between the power source supply terminal and the first input terminal of the first amplifier,
a second diode-connected PMOS transistor which is electrically connected between the power source supply terminal and a second input terminal of the first amplifier,
a first NMOS transistor which is electrically connected between the first input terminal of the first amplifier and the power source ground terminal, and has a gate terminal electrically connected to the output terminal of the first amplifier, and
a second NMOS transistor which is electrically connected between the second input terminal of the first amplifier and the power source ground terminal, and has a gate terminal electrically connected to the output terminal of the first amplifier.

16. The integrated circuit of claim 13, wherein the PAR circuit includes a weighted current mirror which is configured to receive the first type compensation current and weights the first type compensation current that was received with a first gain to produce a weighted first type compensation current, is configured to receive the second type compensation current and weights it with a second gain to produce a weighted second type compensation current, and is configured to output the compensation current by summing the weighted first type compensation current and the weighted second type compensation current.

17. The integrated circuit of claim 12, wherein the PAR circuit comprises:
a three-input amplifier which includes a first input terminal, a second input terminal, and a third input terminal,
a first diode-connected PMOS transistor which is electrically connected between the first input terminal of the three-input amplifier and the power source ground terminal,
a first diode-connected NMOS transistor which is electrically connected between the second input terminal of the three-input amplifier and the power source ground terminal, and
a first resistor which is electrically connected between the third input terminal of the three-input amplifier and the power source ground terminal.

18. The integrated circuit of claim 17, wherein the three-input amplifier includes first, second, third, and fourth amplifier transistors,
wherein the first input terminal of the three-input amplifier is electrically connected to a gate terminal of the first amplifier transistor,
wherein the second input terminal of the three-input amplifier is electrically connected to a gate terminal of the fourth amplifier transistor, and
wherein the third input terminal of the three-input amplifier is electrically connected to gate terminals of the second amplifier transistor and the third amplifier transistor.

19. The integrated circuit of claim 17, wherein the PAR circuit further comprises:
a second diode-connected PMOS transistor which is electrically connected between the third input terminal of the three-input amplifier and the power source ground terminal and has a size larger than that of the first PMOS transistor; and
a second resistor electrically connected between the third input terminal of the three-input amplifier and the second PMOS transistor.

20. (canceled)

21. A phase locked loop circuit comprising:
a loop filter configured to output a control voltage based on an amount of charges stored in a capacitor;
a voltage-current converter configured to receive the control voltage, configured to convert the control voltage into an oscillator control current, and configured to output the oscillator control current; and
an oscillator configured to output an output frequency signal based on the oscillator control current,
wherein the voltage-current converter comprises:
a Process Aware Reference (PAR) circuit configured to output a compensation current that compensates for at least one of a process variation, a power voltage variation, or a temperature variation of the voltage-current converter;
an amplifier which includes a power source terminal that is configured to output an amplifier current that determines an amplifier gain, an inverting input terminal that is configured to receive the control voltage, and a non-inverting input terminal that is configured to receive an amplifier voltage based on the amplifier gain; and
a current digital-analog converter (IDAC) circuit configured to convert a reference current generated based on the amplifier voltage into the oscillator control current in accordance with an IDAC code,
wherein the PAR circuit is configured to output the compensation current to adjust the amplifier current.
